(19) United States
(12) Patent Application Publication
(10) Pub. No.: US 2006/0199358 A1
(43) Pub. Date: Sep. 7, 2006

(54) Method for manufacturing field effect transistor

(75) Inventor: Akira Mineji, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/222,848

(22) Filed: Sep. 12, 2005

(30) Foreign Application Priority Data
Mar. 3, 2005 (JP) 2005-059560

(51) Int. Cl. H01L 21/425

(52) U.S. Cl. 438/530

(57) ABSTRACT

The manufacturing stability can be improved while effectively inhibiting the short-channel effect in the transistor according to the present invention. A halo impurity having a conductivity type opposite to a first conductivity type of a first impurity is ion-implanted into the silicon substrate 101, and thereafter, the first impurity having the first conductivity type is ion-implanted, and then a laser beam is irradiated on a region where the first impurity is doped under a condition so that the silicon substrate 101 is not melted to form a p-type halo region 113 and a n-type extension region 111. Then, the second impurity having the first conductivity type is ion-implanted into the silicon substrate 101, and a laser beam is irradiated on a region where the second impurity is doped under a condition so that the silicon substrate 101 is not melted to form a n-type source/drain region 109.

This application is based on Japanese patent application NO. 2005-059560, contents of which are incorporated hereinto by reference.

### BACKGROUND OF THE INVENTION

1. Field of the Invention

The present invention relates to a method for manufacturing a field effect transistor.

2. Related Art

In order to achieve more rapid operation of a field effect transistor, technological developments such as providing a very short gate length of the field effect transistor, providing a shallow source/drain region and the like are proceeded. Such technologies include a technology described in Japanese Patent Laid-Open No. 2004-253,446.

Japanese Patent Laid-Open No. 2004-253,446 has pointed out a fact that, in the process for manufacturing a metal oxide semiconductor (MOS) transistor, a redistribution of an implanted impurity is occurred corresponding to a diffusion of the implanted impurity during an annealing process after the ion implantation process, and therefore a dispersion of the impurity due to the redistribution of ions should be avoided for the purpose of providing a considerably reduced gate length and/or providing a shallow source drain. It is also described therein that a transient enhanced diffusion (TED) becomes a problem in recent years as a factor for causing the redistribution corresponding to the diffusion of the implanted impurity, and that the TED is a phenomenon, in which a redistribution of the impurity is occurred at a relatively lower temperature and is caused by point defects created in the semiconductor substrate during the ion implantation process.

According to Japanese Patent Laid-Open No. 2004-253,446, it is described that a MOS transistor can be obtained, which provides smaller variation of impurity profile in the source/drain region caused by a heat treatment in the process for forming side wall films of a gate electrode and involves inhibiting a diffusion of an impurity caused by the TED and the corresponding short-channel effect, by establishing an annealing temperature in consideration of a re-diffusion length characteristic for the impurity over the annealing temperature after the ion implantation process and by determining a sequential order of the ion implantation processes.

While the technical field is different therefrom, Japanese Patent Laid-Open No. 2004-158,627 also describes a technology of employing a coherent light irradiation for activating an impurity that has been ion-implanted into substrate in the process for forming a MOS transistor.

### SUMMARY OF THE INVENTION

However, the present inventor has examined the technology described in the above-described Japanese Patent Laid-Open No. 2004-253,446, and found that there is a room for an improvement in view of providing a stable manufacture of the semiconductor device that involves better ability for inhibiting the short-channel effect in such type of MOS transistor.

In such circumstances, the present inventor has investigated a possible cause for the short-channel effect in the transistor in the technology described in Japanese Patent Laid-Open No. 2004-253,446. As a result thereof, the following knowledge has been found. In the technology described in Japanese Patent Laid-Open No. 2004-253,446, the semiconductor substrate is heated by a rapid thermal annealing (RTA) to conduct a process for eliminating defects created in the ion implantation process. Since this method necessarily includes a diffusion of an impurity in principle, there is a concern that the deterioration due to the short-channel effect may be occurred, and therefore there is a room for an improvement in view of providing a manufacturing stability.

The present inventor has eagerly investigated for providing a solution to the above-stated problem. As the result of the investigation, it has been found that the manufacturing stability can be improved while effectively inhibiting the short-channel effect in the transistor, by conducting an annealing process for the purpose of eliminating the defect employing a laser annealing under a predetermined condition, thereby leading to the present invention.

According to one aspect of the present invention, there is provided a method for manufacturing a field effect transistor, comprising: forming a gate electrode in an element formation surface of a semiconductor substrate and ion-implanting an impurity having a first conductivity type into a region of the semiconductor substrate being in vicinity of the gate electrode; conducting a laser annealing by irradiating a laser beam on a region where the impurity having the first conductivity type is implanted after the ion-implanting the impurity having the first conductivity type under a condition so that the semiconductor substrate is not melted; and activating the impurity contained in a impurity-implanted region by conducting a heat treatment over the semiconductor substrate after the conducting the laser annealing.

In a manufacturing method of field effect transistor according to the above-described aspect of the present invention, a laser annealing is conducted by irradiating the laser beam on the region where the impurity having the first conductivity type is implanted under the condition so that the semiconductor substrate is not melted, after ion-implanting the impurity having the first conductivity type and before the heat treatment process that activates the impurity included in the impurity-implanted region. According to the aspect of the invention, the elimination of the lattice defects created in the impurity-doped region during the ion implantation process can be ensured before the heat treatment process is conducted. Therefore, the redistribution of the impurity, which may be otherwise caused during the heat treatment due to the point defects created in the semiconductor substrate in the ion implantation process, can be inhibited. Thus, the generation of the short-channel effect can be inhibited, even if the gate length of the field effect transistor is reduced. Therefore, the reduction of the threshold voltage (Vₜₕ) of the field effect transistor can be inhibited, so that the characteristics for the use as the transistor can be improved.

Further, in the method for manufacturing the field effect transistor according to the present invention, the laser beam may be irradiated under the condition so that the semiconductor substrate is not melted. Thus, an additional heating process for eliminating lattice defects, which may be otherwise generated due a recrystallization after the melting thereof, can be omitted. Further, the region containing the defects created in the ion implantation process can be selectively heated by irradiating the laser beam on the region where the impurity having the first conductivity type is doped. Thus, the lattice defects can be stably eliminated by the simple method.

According to another aspect of the present invention, there is provided a method for manufacturing a field effect transistor, comprising: forming a gate electrode in an element formation surface of a semiconductor substrate and providing a halo region and an extension region in regions of the semiconductor substrate being in vicinity of the gate electrode; and providing a source/drain region in the semiconductor substrate, after the providing the halo region and the extension region; wherein the providing the halo region and the extension region includes a first ion implantation process that comprises ion-implanting a first impurity having a first conductivity type into the semiconductor substrate and a first laser annealing process that comprises irradiating a laser beam on a region implanted with the first impurity with a condition such that the semiconductor substrate is not melted after the first ion implantation process, and wherein the providing the source/drain region includes a second ion implantation process that comprises ion-implanting a second impurity having the first conductivity type into the semiconductor substrate after the first laser annealing process, and a second laser annealing process that comprises irradiating a laser beam on a region implanted with the second impurity with a condition such that the semiconductor substrate is not melted after the second ion implantation process.

In the method for manufacturing the field effect transistor according to the above-described aspect of the present invention, a laser annealing is carried out after the ion implantation process in each of the processes for providing the halo region and the extension region and for providing the source/drain region. According to such method, crystal defects in the impurity-doped region created by the ion implantation process can be eliminated before the process for providing the source/drain region during the process for forming the halo region and the extension region. Therefore, a redistribution of the impurity that has been ion-implanted into the halo region and the extension region can be inhibited during the heat treatment process conducted after the process for forming the halo region and the extension region and more specifically during a heat treatment in the process for forming the side wall insulating film in the peripheral regions of the gate electrode, for example.

Further, according to such manufacturing method, the crystal defects created during the ion implantation process of the second ion implantation process can be surely eliminated before the heat treatment process conducted after forming the source/drain region. Therefore, the redistribution of the impurity, which may be otherwise caused during the heat treatment due to the point defects created in the semiconductor substrate in the ion implantation process, can be inhibited. Thus, the generation of the short-channel effect can be inhibited, even if the gate length of the field effect transistor is reduced. As described above, the decrease of the threshold voltage (Vₜₕ) of the field effect transistor can be prevented to provide an improved characteristic for the use as the transistor, by providing the laser annealing process after each of the ion implantation processes and before the earliest heat treatment process thereafter.

According to the present invention, a laser annealing is conducted by irradiating a laser beam on a region where the impurity having the first conductivity type is implanted under a condition so that the semiconductor substrate is not melted, after ion-implanting the impurity having the first conductivity type and before conducting the heat treatment process for the semiconductor substrate, such that the technology that provides the improved manufacturing stability while effectively inhibiting the short-channel effect in the transistor can be achieved.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, showing a configuration of a semiconductor device in an embodiment of the present invention;

FIGS. 2A, 2B and 2C are cross-sectional views, illustrating a procedure for manufacturing the semiconductor device of FIG. 1;

FIGS. 3A, 3B and 3C are cross-sectional views, illustrating a procedure for manufacturing the semiconductor device of FIG. 1;

FIG. 4 is a flow chart, showing a procedure for manufacturing the semiconductor device in the embodiment of the present invention;

FIG. 5 is a cross-sectional view, showing a configuration of a semiconductor device in another embodiment of the present invention;

FIGS. 6A, 6B and 6C are cross-sectional views, illustrating a procedure for manufacturing the semiconductor device of FIG. 5; and

FIGS. 7A, 7B and 7C are cross-sectional views, illustrating a procedure for manufacturing the semiconductor device of FIG. 5.

### DETAILED DESCRIPTION OF THE PREFERRED EMBODIMENT

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments according to the present invention will be described as follows in further detail, in reference to the annexed figures. In all figures, identical numeral is assigned to an element commonly appeared in the figures, and the detailed description thereof will not be presented.

### First Embodiment

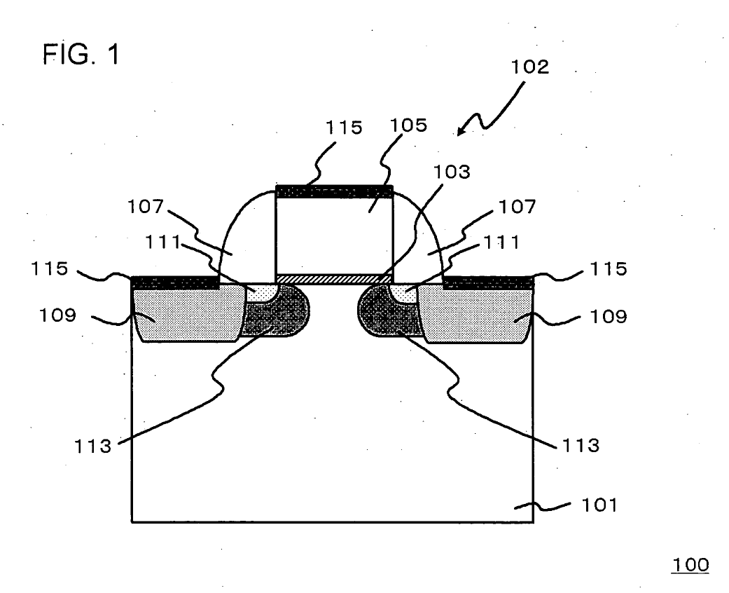

FIG. 1 is a cross-sectional view, schematically showing a configuration of a semiconductor device according to the present embodiment. A semiconductor device 100 shown in FIG. 1 comprises a n-type metal oxide semiconductor field effect transistor (MOSFET) 102. While it is not shown in FIG. 1, an element-separating region is provided in a peripheral portion of the n-type MOSFET 102.

In the n-type MOSFET 102, a pair of n-type source/drain regions 109 is provided in a silicon substrate 101 having p-type conductivity, and a channel region (not shown) is formed between the regions. The n-type source/drain region 109 is an impurity-diffusing region functioning as a source region or a drain region. A SiON film is provided on the channel region as a gate insulating film 103, and a polycrystalline silicon film that functions as a gate electrode 105 is formed on the SiON film so as to contacted therewith. Further, a side wall insulating film 107 that covers side walls of the gate insulating film 103 and the gate electrode 105 is provided. A Ni silicide layer 115 is provided on an upper portion of the gate electrode 105 and on a region of an upper portion of the n-type source/drain region 109 that has no side wall insulating film 107 formed thereon.

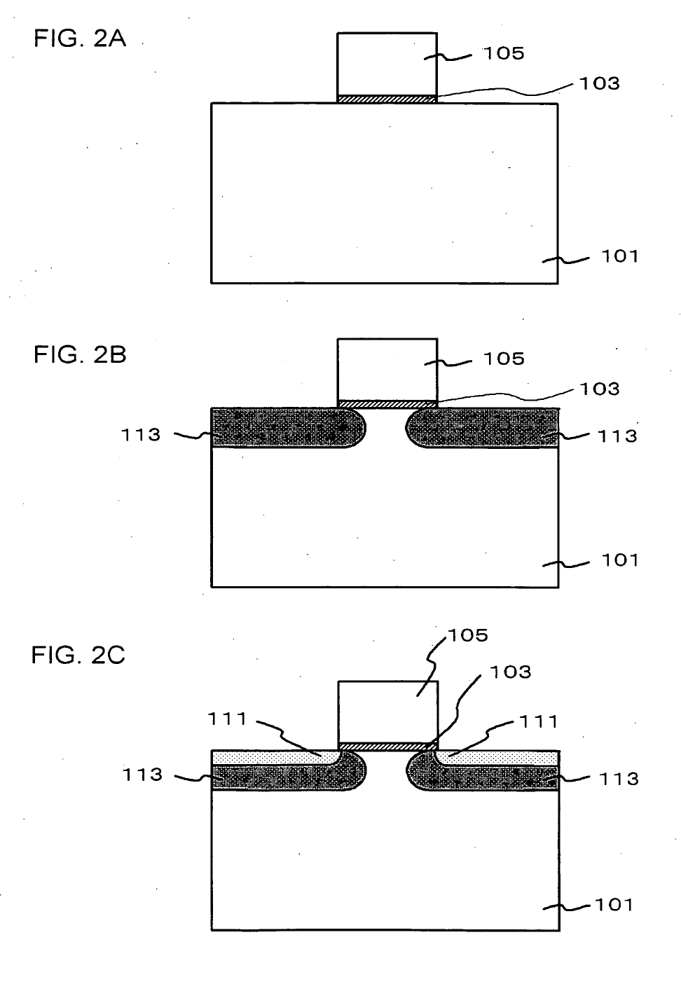

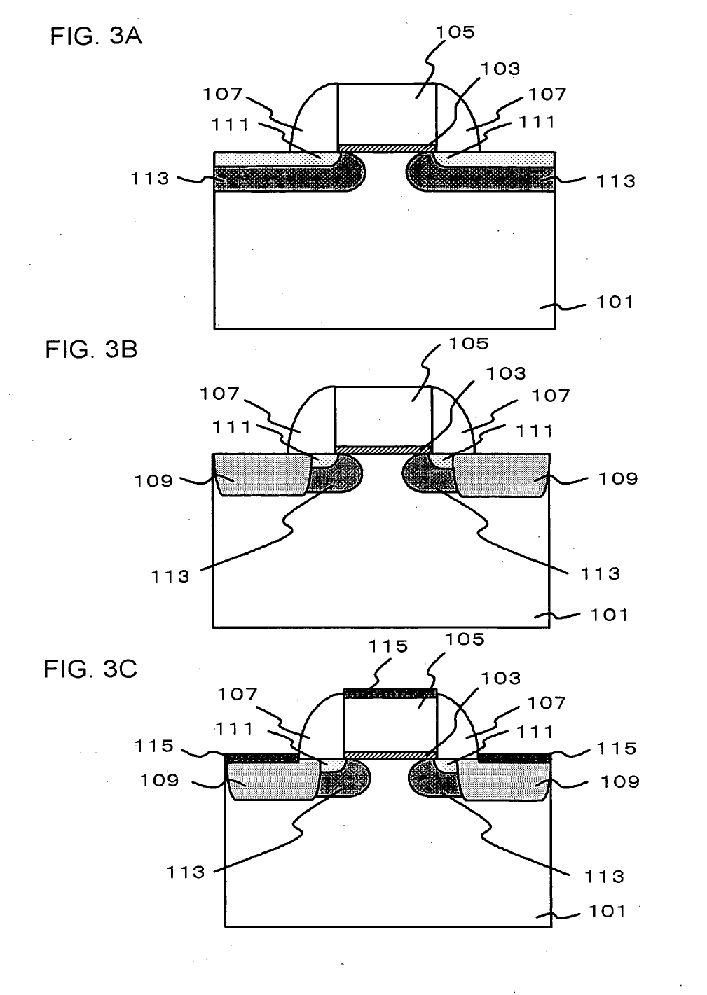

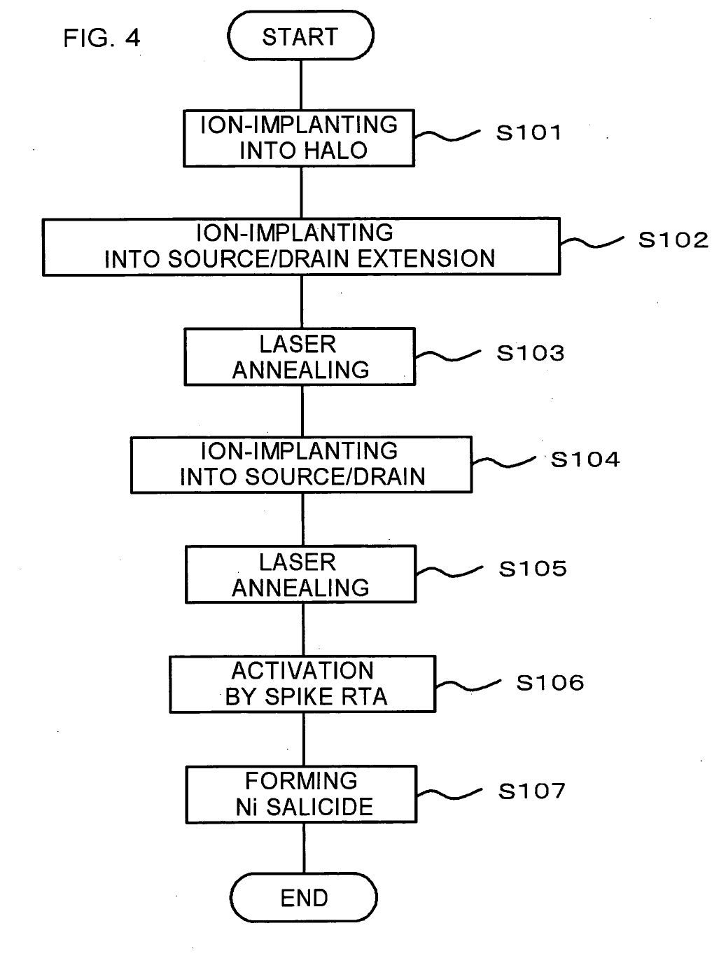

Next, a method for manufacturing the semiconductor device 100 shown in FIG. 1 will be described. The semiconductor device 100 is obtained by providing the n-type MOSFET 102 on the silicon substrate 101. FIG. 2A to FIG. 2C and FIG. 3A to FIG. 3C are cross-sectional views, illustrating a procedure for manufacturing the n-type MOSFET 102. FIG. 4 is a flow chart, showing a procedure for manufacturing the n-type MOSFET 102. The description will be made in reference to these drawings.

The method for manufacturing the n-type MOSFET 102 of the present embodiment comprises: forming a gate electrode 105 on an element formation surface of the semiconductor substrate (silicon substrate 101) and ion-implanting or doping an impurity having a first conductivity type in portions of the silicon substrate 101 being in vicinity thereof (S102, S104 in FIG. 4); after ion-implanting or doping the impurity having the first conductivity type, conducting a laser annealing process by irradiating a laser beam on a region where the impurity having the first conductivity type is doped, under a condition so that the silicon substrate 101 is not melted (S103, S105); and after the process of conducting the laser annealing, activating the impurity contained in an impurity-implanted region by conducting a heat treatment of the silicon substrate 101 (S106):

Further, the method for manufacturing the n-type MOSFET 102 of the present embodiment comprises: forming a gate electrode 105 on an element formation surface of the silicon substrate 101 and providing a halo region (p-type halo regions 113) and an extension region (n-type extension region 111) in portions of the semiconductor substrate being in vicinity thereof (S101 to S103); and after the process of providing the p-type halo region 113 and the n-type extension region 111, providing the source/drain region (n type source/drain region 109) in the silicon substrate 101 (S104 and S105).

The process for providing the p-type halo region 113 and the n-type extension region 111 includes: a first ion implantation process that comprises, after ion-implanting a halo impurity having a conductivity type that is opposite to the first conductivity type for the first impurity into the silicon substrate 101 (S101), ion-implanting a first impurity having a first conductivity type (S102); and a first laser annealing process that comprises, after the first ion implantation process, irradiating a laser beam on a region where the first impurity is doped, under a the condition so that the silicon substrate 101 is not melted (S103).

The aforementioned process for providing the n-type source/drain region 109 includes: a second ion implantation process that comprises, after the first laser annealing process, ion-implanting a second impurity having the first conductivity type (n-type) into the silicon substrate 101 (S104); a second laser annealing process that comprises, after the second ion implantation process, irradiating a laser beam on a region where the second first impurity is doped under the condition so that the silicon substrate 101 is not melted (S105)

The method also includes, after the second laser annealing process, activating the first impurity (n-type impurity), the second impurity (n-type impurity) and the p-type impurity contained in the impurity-implanted region (n-type source/drain region 109, p-type halo region 113 and n-type extension region 111) by conducting a heat-treatment over the silicon substrate 101.

The process for conducting the heat-treatment over the silicon substrate 101 includes elevating a temperature of an element formation surface to a temperature of equal to or higher than 500 degree C.

More specifically, the aforementioned process for conducting the heat-treatment over the silicon substrate 101 includes activating the impurity having the first conductivity type by heating the silicon substrate 101 via the spike RTA (S106).

The method also includes, after the process for conducting the heat-treatment over the silicon substrate 101, forming a Ni salicide (S107), and providing a silicide layer (Ni silicide layer 115) on the upper portion of the gate electrode 105 and the upper portion of the n-type source/drain region 109.

The process for irradiating a laser beam under the condition so that the silicon substrate 101 is not melted includes irradiating a laser beam so that the highest available temperature of the element formation surface is lower than 1,412 degree C.

The method for manufacturing the semiconductor device 100 having the n-type MOSFET 102 will be described more in detail as follows.

First, as shown in FIG. 2A, an element separating region (not shown) of a shallow trench isolation (STI) is formed by employing a known technology on the silicon substrate 101 having a principal surface of, for example, (100) plane. The element-separating region may be formed by another known method such as local oxidation of silicon (LOCOS). Then, a SiON film and a polycrystalline silicon film are sequentially deposited on the silicon substrate 101 to form a multiple-layered structure, and thereafter, the formed multiple-layered structure is selectively dry-etched to form geometry for the gate insulating film 103 and the gate electrode 105. The SiON film is formed by, for example, a thermal oxidation and a plasma nitridation.

Next, a p-type halo region 113 is formed in a region of the silicon substrate 101 for forming the n-type MOSFET 102 (FIG. 2B). The p-type halo region 113 is provided at an end of the n-type source/drain region 109 under the gate electrode 105, and is presented as an impurity-diffusing region for impurity having a conductivity type, which is the same type as that of the channel region. Since the p-type halo region 113 functions as a punch-through stopper region, the short-channel effect can be inhibited by providing the p-type halo region 113.

The p-type halo region 113 is, more specifically, formed by ion-implanting indium (In) therein through the gate electrode 105 as a mask under a condition of tilting the silicon substrate 101 by, for example, 30 degrees from normal line to the surface of the silicon substrate 101 (tilt angle of 30 degrees), while spinning the whole silicon substrate 101 (S101 in FIG. 4). The condition for the ion-implantation of In is, for example, at an energy of 60 keV and with a dose amount of 2×10¹³ atoms/cm². Alternatively, boron (B) or an impurity containing boron such as bromine fluoride (BF₂) and the like may be ion-implanted, in place of In.

Subsequently, a n-type extension region 111 is formed (FIG. 2C). More specifically, an ion-implantation with arsenic (As) is conducted along a direction that is parallel to normal line of the silicon substrate 101 (tilt angle: zero degree) through the gate electrode 105 as a mask under the condition of at an energy of 2 keV and with a dose amount of 5×10¹⁴ atoms/cm² (S102 in FIG. 4). As a result, the p-type halo region 113 and the n-type extension region 111 are formed in a manner of self-aligning against the gate electrode 105.

Then, a laser thermal annealing (LTA) process is conducted for the p-type halo region 113, in which indium (In) is ion-implanted, and for the n-type extension region 111, in which arsenic (As) is ion-implanted, under the condition so that the silicon substrate 101 is not melted (S103 in FIG. 4). In this occasion, for example, the highest available temperature of the element formation surface of the silicon substrate 101 may be selected to a temperature level that does not cause melting of the silicon substrate 101, and more specifically to a temperature of equal to or higher than 900 degree C., and preferably to a temperature of equal to or higher than 1,000 degree C. Providing such condition, lattice defects created during the ion implantation process can be surely eliminated, and the diffusion of the impurity, which is otherwise generated in heating process conducted after the laser annealing process of step 103, can be surely inhibited. Further, the highest available temperature of the element formation surface of the silicon substrate 101 may be selected to be, for example, lower than the melting point of silicon (Si) (1,412 degree C.), and preferably equal to or lower than 1,400 degree C. Providing such condition, a local melting of the silicon substrate 101 can be inhibited, and therefore the defect in the crystal lattice of Si composing the silicon substrate 101 can be surely reduced.

Further, the duration time for the laser annealing process may be on the order of several hundred or several ten milliseconds, for example. The duration time for the laser annealing process can be set depending on the wavelength and the irradiated energy density of a laser beam. In addition, the duration time for the leaser annealing process may be equal to or shorter than 100 milliseconds, and preferably equal to or shorter than ten milliseconds. Having such configuration, the lattice defects can be more stably eliminated.

Here, the method for irradiating a laser beam in the laser annealing process may be suitably selected such that the selected method provides the above-described temperature condition and the irradiation time.

After the laser annealing, as shown in FIG. 3A, a side wall insulating film 107 is formed on the side wall of the gate electrode 105. The side wall insulating film 107 is obtained by, for example, forming a silicon oxide film on the entire surface of the silicon substrate 101 via a chemical vapor deposition (CVD) and then conducting an etchback thereof. When the silicon oxide film is formed via the CVD, the silicon substrate 101 is heated to a temperature of around 500 to 600 degree C., for example.

Then, the n-type source/drain region 109 is formed in a region for forming the n-type MOSFET 102 (FIG. 3B). The n-type source/drain region 109 is formed by ion-implanting a n-type impurity (S104 in FIG. 4). Arsenic (As) may be employed for the n-type impurity, for example, and the process conditions in this case may be, for example, at 25 keV and with 5×10¹⁵ atoms/cm².

Subsequently, the laser annealing process for the n-type source/drain region 109 is conducted under the condition so that the silicon substrate 101 is not melted (S105 in FIG. 4). The condition of the laser annealing may be, for example, same as the annealing condition in the laser annealing of step 103 in FIG. 4.

Thereafter, the activation of impurity is conducted by thermally processing the silicon substrate 101 within a non-oxidizing atmosphere (S106 in FIG. 4). The impurity doped in the silicon substrate 101 is electrically activated by conducting such heat treatment. Although the condition for the heat treatment depends on the type of the doped impurity, an exemplary condition may be, for example, that a spike rapid thermal annealing (RTA) is employed to heat the silicon substrate 101 to for example, highest available temperature of 1,050 degree C., and thereafter, the temperature is immediately decreased. The heating rate in the spike RTA process may be, for example, equal to or higher than 150 degree C./sec., and preferably equal to or higher than 250 degree C./sec. This can further ensure the activation of the impurity.

Then, a Ni salicide process is conducted (S107 in FIG. 4) to form a Ni silicide layer 115 on the upper portions of the gate electrode 105 and the n-type source/drain region 109 (FIG. 3C). A reduction in the resistance of the surfaces of the gate electrode 105 and the n-type source/drain region 109 can be achieved by providing the Ni silicide-layer 115. Conventionally known methods may be employed for the formation of the Ni silicide layer 115. For example, Ni is deposited on the entire surface of the element formation surface of the silicon substrate 101 by a sputtering, and thereafter, the annealing thereof is conducted at a low temperature to form a meta-stable silicide. Then, unreacted residual Ni is removed by a wet process. Subsequently, an annealing is conducted at a predetermined temperature so that Ni is reacted with Si to form a silicide. The semiconductor device 100 having the n-type MOSFET 102 (FIG. 1) is obtained by conducting the above-mentioned process.

Next, advantageous effects obtainable by employing the configuration of the semiconductor device 100 shown in FIG. 1 will be described. In the semiconductor device 100, the n-type MOSFET 102 is manufactured by conducting the laser annealing process (S103 and S105 in FIG. 4) as a process for eliminating defects that have been created in the ion implantation process, between the process for ion-implanting to the silicon substrate 101 and a heating process that is the earliest heating process conducted thereafter. More specifically, the laser annealing of step 103 is conducted after the ion implantation into the n-type extension region 111 in step 102 and before the heating process conducted during the process for forming the side wall insulating film 107. Further, after the ion implantation into the n-type source/drain region 109 in step 104 and before the annealing process for the activation in step 106, the laser annealing process of step 105 is conducted. In this way, the laser annealing processes are carried out for the respective ion implantation processes. Having such configuration, the diffusion of the impurity, which has been doped therein during each of the ion implantation processes, caused in the heat treatment process due to lattice defects created in each of the ion implantation processes, can be inhibited, and the inhibition of the enhanced diffusion of the impurity in the activation annealing process (S106 in FIG. 4) can also be inhibited. Thus, the generation of the short-channel effect can be inhibited even in the case of having a configuration comprising the miniaturized gate electrode 105 and side wall insulating film 107, or in other words, even in the case of having a configuration that the gate length of the n-type MOSFET 102 is shorter. Therefore, the configuration that provides inhibiting the decrease of the threshold voltage (Vₜₕ) of the n-type MOSFET 102 and provides better characteristics for the use as the transistor can be presented.

Further, the region containing ions implanted therein can be selectively heated with higher efficiency, by employing the laser annealing process for the process of eliminating the defects in the ion implantation process.

In the technology described in Japanese Patent Laid-Open No. 2004-253,446, which has been described in the description of the related art, the entire surface of the silicon substrate 101 is heated by the RTA. Thus, a temperature gradient along the depth direction is occurred for the whole silicon substrate 101, and thus there is a concern that a generation of a stress and the corresponding generation of deterioration in the device and the silicon substrate 101 are occurred. On the contrary, according to the present embodiment, the region containing the defect generated by the ion implantation process can be selectively heated by irradiating a laser beam having comparatively longer wave only on the predetermined region.

Further, the RTA process involves adverse features, including that the upper limit of the highest available temperature of the silicon substrate 101 is lower than 1,412 degree C. that is a melting point of Si, and the time required for the heating is relatively longer, for example, a time longer than one second. On the contrary, since the present embodiment employs the laser annealing, the silicon substrate 101 can be surely heated to a temperature that is slightly lower the melting point of silicon. In addition, more efficient heating process, which requires shorter heating time than that required in the RTA, can be achieved. Therefore, the point defects created in the semiconductor substrate by the ion implantation process can be eliminated with higher efficiency, such that the short-channel effect of the transistor is inhibited.

In such case, excessively shorter wave length of the laser beam irradiating on the silicon substrate 101 may possibly provide a pattern dependency in the feature of the heating, due to a difference in an absorbancy index according to types of the film in vicinity of the element formation surface. On the other hand, there is a concern that longer wave length of the laser beam may lead to an insufficient heat absorption of the silicon substrate 101. Thus, in the present embodiment and the following embodiments, wave length of a laser beam is suitably selected, based on the careful consideration of these concerns.

As described above, the n-type MOSFET 102 has the configuration that provides better manufacturing stability, by providing the elimination of the defects, which have been generated in the ion implantation process, via the laser annealing.

In the meantime, it is described in Japanese Patent Laid-Open No. 2004-158,627, which has been described in the description of the related art, that it is preferable to collectively conduct the activation processes after forming a shallow ion-implanted layer and a deep ion-implanted layer. However, in such case, there is a concern that impurity contained in the shallow ion-implanted layer is diffused or a non-recoverable lattice defect is remained therein, by a heat treatment process conducted in the formation of the side wall after forming the shallow ion-implanted layer. Therefore, there is a concern that the transistor characteristics can not be sufficiently maintained.

On the contrary, the configuration of the present embodiment provides an inhibition to the diffusion of the impurity and the remaining of the lattice defects, by having laser annealing processes after forming the n-type extension region 111 and after forming the n-type source/drain region 109, respectively. In addition, the present embodiment provides a separate activation process (S106 in FIG. 4) after the laser annealing process, so that the activation via the spike RTA is conducted. Having such configuration, a predetermined region is selectively heated to eliminate crystal defects in step 103 and step 105, and the entire surface of the silicon substrate 101 is heated in step 106 to surely activate the impurity and suitably diffuse the impurity, so that an appropriate junction depth can be ensured and the conjunction that is not very shallow can be provided. Therefore, the characteristics of the n-type MOSFET 102 for the use as the transistor can be improved.

In addition, it is also described in Japanese Patent Laid-Open No. 2004-158,627 that, since it is necessary to provide a level of energy (quantity of heat), which is sufficient to activate the impurity ion-implanted therein, onto the surface of the substrate, suitable irradiation condition of the laser beam is required.

On the contrary, when the semiconductor device 100 is manufactured in the present embodiment, it is sufficient to have an integrated value of an energy per a unit volume (that is, quantity of heat), which is provided onto a predetermined location on the silicon substrate 101 by irradiating a laser beam in step 103 and step 105 (FIG. 4), at a level that can eliminate the crystal defects derived from the ion implantation process, and it is not necessary to have it at higher level that promotes activating the impurity. Consequently, the present embodiment requires only a smaller integrated value of the energy per a unit volume (quantity of heat) that is smaller than the value required for irradiating a laser beam on the substrate surface in the technology described in Japanese Patent Laid-Open No. 2004-158,627.

In the following embodiment, different points from first embodiment will be mainly described.

### Second Embodiment

While the example of the semiconductor device 100 having the n-type MOSFET 102 is described in the first embodiment, the a configuration of the present invention may also be applied to a complementary metal oxide semiconductor field effect transistor (CMOSFET).

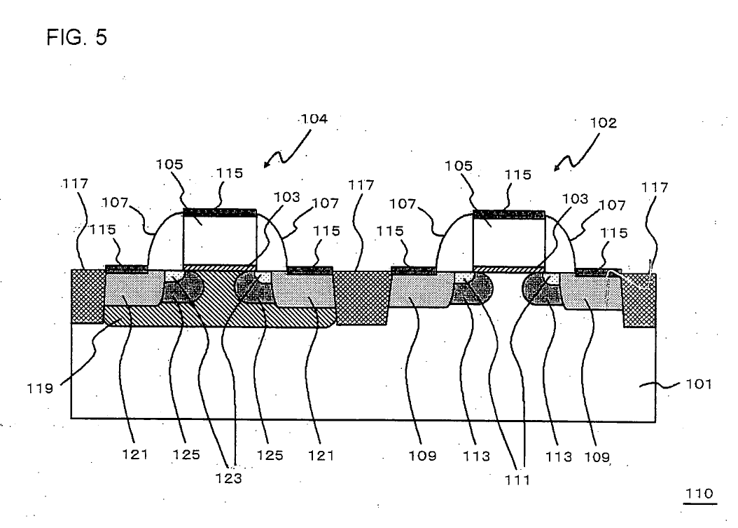

FIG. 5 is a cross-sectional view, illustrating a configuration of a semiconductor device of the present embodiment. A semiconductor device 110 shown in FIG. 5 comprises a CMOSFET composed of the n-type MOSFET 102 shown in FIG. 1 and a p-type MOSFET 104.

The p-type MOSFET 104 is physically isolated and electrically insulated from the n-type MOSFET 102 by an element separating region 117. The p-type MOSFET 104 is formed in a n-type well 119 provided in the silicon substrate 101. The p-type MOSFET 104 also comprises a n-type halo region 125, a p-type extension region 123 and a p-type source/drain region 121, in place of the n-type source/drain region 109 of the n-type MOSFET 102, the n-type extension region 111 and the p-type halo region 113, respectively.

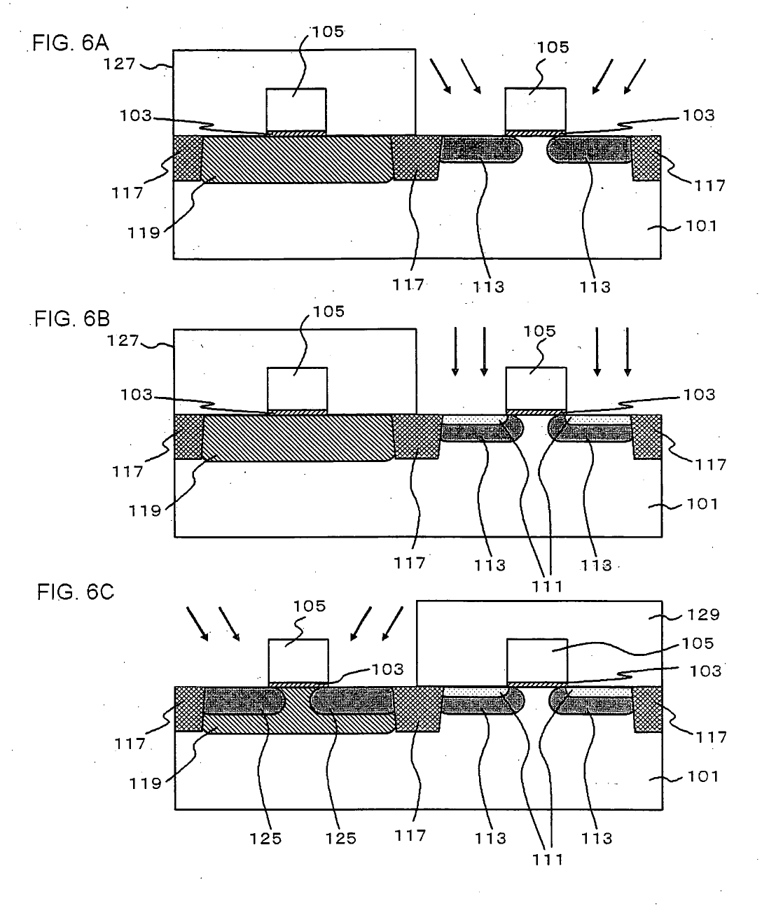

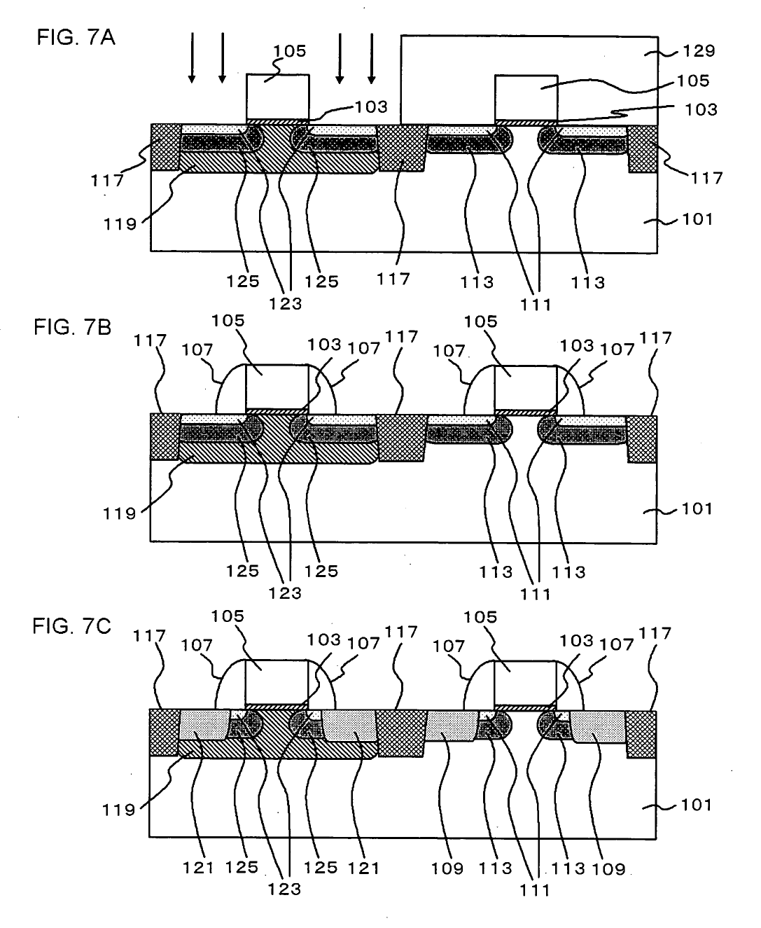

FIG. 6A to FIG. 6C and FIG. 7A to FIG. 7C are cross-sectional views, illustrating a process for manufacturing the semiconductor device 110 shown in FIG. 5. The process for manufacturing the semiconductor device 110 will be described as below in reference to these drawings.

First, as shown in FIG. 6A, the element separating region 117, which isolates the n-type MOSFET 102 from the p-type MOSFET 104, is formed in the p-type silicon substrate 101. The element separating region 117 may be, for example, a STI formed by a known method, similarly as in the first embodiment. Then, the region for forming the p-type MOSFET 104 is doped or ion-implanted with phosphorus (P) as a n-type impurity to form a n-type well 119. Subsequently, similarly as in the first embodiment, a gate insulating films 103 and a gate electrodes 105 are formed in the regions for forming the n-type MOSFET 102 and the p-type MOSFET 104, respectively.

Then, the region for forming the p-type MOSFET 104 is covered with a mask 127, and the p-type halo region 113 is formed (FIG. 6A) similarly as in the first embodiment (FIG. 2B). Further, a n-type extension region 111 is formed (FIG. 6B), similarly as in the first embodiment (FIG. 2C).

Subsequently, the mask 127 is stripped, and thereafter, the region for forming the n-type MOSFET 102 is covered with a mask 129.

Then, a n-type halo region 125 is formed in the region for forming the p-type MOSFET 104 (FIG. 6C). More specifically, the n-type halo region 125 is formed by ion-implanting arsenic (As) through the gate electrode 105 as a mask, while tilting the silicon substrate 101 by, for example, 30 degrees from normal line direction of the silicon substrate 101 (tilt angle: 30 degrees). The conditions for the ion-implantation of As is, for example, at an energy of 45 keV and with a dose amount of 2×10¹³ atoms/cm². Alternatively, phosphorus (P) may be ion-implanted, in place of As.

Then, a p-type extension region 123 is formed while maintaining the status of covering the region for forming the n-type MOSFET 102 with the mask 129 (FIG. 7A). More specifically, an ion-implantation with boron fluoride (BF₂) is conducted along a direction that is parallel to the surface of the silicon substrate 101 (tilt angle: zero degree) through the gate electrode 105 as a mask, under the condition of at an energy of 2 keV and with a dose amount of 5×10¹⁴ atoms/cm². As a result thereof, the p-type extension region 123 and a n-type halo region 125 are formed in a manner of self-aligning against the gate electrode 105. Here, the impurity for the ion-implanting may be boron, in place of boron fluoride.

Next, the mask 129 is stripped, and then, a laser annealing process for the n-type extension region 111, the p-type halo region 113, the p-type extension region 123 and n-type halo region 125 is conducted under the condition so that the silicon substrate 101 is not melted (S103 in FIG. 4). Process conditions for the laser annealing process may be, for example, the condition same as employed in the first embodiment.

After conducting the laser annealing process, a side wall insulating film 107 is formed on the side wall of the gate electrode 105, as shown in FIG. 7B. The formation of the side wall insulating film 107 may be carried out by, for example, the procedure described above in reference to FIG. 3A.

Then, the region for forming the p-type MOSFET 104 is covered with a mask (not shown), and the ion-implantation into the region for forming the n-type MOSFET 102 is conducted to form the n-type source/drain region 109. In addition, the region for forming the n-type MOSFET 102 is covered with a mask (not shown), and the ion-implantation into the region for forming the p-type MOSFET 104 is conducted to form the p-type source/drain region 121 (FIG. 7C). Here, boron (B), for example, may be employed as a p-type impurity for ion-implanting into the p-type source/drain region 121. Process conditions for the implantation may be, for example, at 2 keV and with 5×10¹⁵ atoms/cm².

Thereafter, the laser annealing process for the n-type source/drain region 109 and the p-type source/drain region 121 is conducted under the condition that the silicon substrate 101 is not melted (S105 in FIG. 4). Process conditions of the laser annealing process may be, for example, same as the annealing condition employed in the first embodiment.

Thereafter, similarly as in the first embodiment, the spike RTA process is conducted within a non-oxidizing atmosphere to activate the impurity that has been ion-implanted into silicon substrate 101 (S106 in FIG. 4). Then a Ni silicide layer 115 is formed on upper portions of the gate electrode 105, the n-type source/drain region 109 and the p-type source/drain region 121. According to the above-described process, the semiconductor device 110 (FIG. 5) having the n-type MOSFET 102 and the p-type MOSFET 104 is obtained.

The semiconductor device 110 of the present embodiment is manufactured by conducting the laser annealing process after forming the halo regions and the extension regions of the n-type MOSFET 102 and the p-type MOSFET 104 and before conducting the heating process (S103 in FIG. 4), and by conducting the laser annealing process after forming the source/drain region and before conducting the activation process that is the earliest heat-treatment process thereafter (S105 in FIG. 4). Thus, the defect-recovering effect same as obtained in the first embodiment can be obtained, and a generation of a contamination material during the manufacturing process in each of the n-type MOSFET 102 and the p-type MOSFET 104 composing the CMOSFET can be inhibited. Thus, in each of the n-type MOSFET 102 and the p-type MOSFET 104, the short-channel effect is inhibited.

While the preferred embodiments of the present invention have been described above in reference to the annexed figures, it should be understood that the disclosures above are presented for the purpose of illustrating the present invention, and various configurations other than the above-described configurations can also be adopted.

For example, the earliest heating process after the process for forming the halo region is the process for forming the side wall insulating film in the above described embodiments. The first heating process after the process for forming the extension region is also the process for forming the side wall insulating film. Thus, the laser annealing process (S103) is conducted just after the process for forming the extension region (S102) in FIG. 4. On the contrary, in the case of the manufacturing process including the heat-treatment process after forming the halo region (S101) and before forming the extension region (S102), an additional laser annealing process may be conducted before the heat-treatment process. Having such configuration, the lattice defects created in the ion implantation in the process of forming the halo region can be eliminated before the heat treatment process, so that the diffusion of the impurity doped into the halo region can be prevented.

While the case that the earliest heating process after the ion implantation is the heating process in the process for forming the side wall insulating film 107 or activation-annealing process (S106) have been illustrated in the above described embodiments, the laser annealing process can also be equally conducted before the heating process, even if the earliest heating process thereafter is a process other than the above-described processes.

Further, SiO₂ film may be employed as the gate insulating film 103, in place of SiON film, in the above embodiments.

### EXAMPLES

In the following example, a semiconductor device 100 described in the first embodiment (FIG. 1) was manufactured.

### Example 1

A semiconductor device 100 comprising a p-type MOSFET 104 was manufactured via the procedure shown in FIG. 4. In step 103 and step 105, a laser beam was continuously irradiated. In this case, the highest available temperature was set to 1,400 degree C. Here, in this example and the following examples, the heating temperature during the formation of the side wall insulating film 107 was set to 700 degree C. In addition, in the spike RTA of step 106, a heating rate was set to 250 degree C./sec., and highest available temperature for the surface of the silicon substrate 101 was set to 1,050 degree C.

### Example 2

A semiconductor device 100 was manufactured by a process, in which the annealing processes of step 103 and step 105 were substituted for the laser annealing processes in the procedure shown in FIG. 4 to conduct a flashlamp-annealing (FLA) process. The highest available temperature in the flash-lamp annealing was set to 1,300 degree C.

### Example 3

A semiconductor device 100 was manufactured by the procedures shown in FIG. 4, except that the laser annealing of step 103 was not conducted and only the laser annealing of step 105 was conducted.

### Example 4

A semiconductor device 100 was manufactured by the procedures shown in FIG. 4, except that the activation process by the spike RTA of step 106 was not conducted.

(Analysis)

The relationship of the depth (nm) from the surface of the silicon substrate 101 and the concentration of the halo impurity (atoms/cm³) in the p-type halo region 113 and the n-type source/drain region 109 was investigated for the semiconductor devices 100 obtained with example 1 to example 3. The results indicate that a peak clearly appears in the concentration of the impurity for each of the p-type halo region 113 and the n-type source/drain region 109 in the case of the semiconductor device 100 obtained in example 1.

On the contrary, in example 2, a peak of the concentration of the impurity in each of the p-type halo region 113 and the n-type source/drain region 109 is more gentle and lower than that appeared in example 1. In addition, the manufacturing stability in manufacturing n-type MOSFETs 102 for multiple times in example 2 was lower than that obtained in example 1.

Further, in example 3, a peak of the concentration of the impurity in the p-type halo region 113 is more gentle and lower than that appeared in example 1.

Furthermore, concerning the semiconductor device 100 obtained in example 4, while the peaks for the p-type halo region 113 and the n-type source/drain region 109 are slightly sharper than that for the semiconductor device 100 of example 1, the electrical voltage-current characteristics could not sufficiently improved because of the absence of the activation via the spike RTA.

What is claimed is:

1. A method for manufacturing a field effect transistor, comprising:
forming a gate electrode in an element formation surface of a semiconductor substrate and ion-implanting an impurity-having a first conductivity type into a region of said semiconductor substrate being in vicinity of said gate electrode;
conducting a laser annealing by irradiating a laser beam on a region where said impurity having the first conductivity type is implanted after said ion-implanting the impurity having the first conductivity type under a condition so that said semiconductor substrate is not melted; and
activating said impurity contained in a impurity-implanted region by conducting a heat treatment over said semiconductor substrate after said conducting the laser annealing.

2. A method for manufacturing a field effect transistor, comprising:
forming a gate electrode in an element formation surface of a semiconductor substrate and providing a halo region and an extension region in regions of said semiconductor substrate being in vicinity of said gate electrode; and
providing a source/drain region in said semiconductor substrate, after said providing the halo region and the extension region,
wherein said providing the halo region and the extension region includes a first ion implantation process that comprises ion-implanting a first impurity having a first conductivity type into said semiconductor substrate and a first laser annealing process that comprises irradiating a laser beam on a region implanted with said first impurity with a condition such that said semiconductor substrate is not melted after said first ion implantation process, and
wherein said providing the source/drain region includes a second ion implantation process that comprises ion-implanting a second impurity having said first conductivity type into said semiconductor substrate after said first laser annealing process, and a second laser annealing process that comprises irradiating a laser beam on a region implanted with said second impurity with a condition such that said semiconductor substrate is not melted after said second ion implantation process.

3. The method according to claim 2, further comprises activating said first impurity and said second impurity contained in a impurity-implanted region by conducting a heat-treatment for said semiconductor substrate after said second laser annealing process.

4. The method according to claim 1, wherein said conducting the heat-treatment for said semiconductor substrate comprises heating said element formation surface to a temperature of equal to or higher than 500 degree C.

5. The method according to claim 3, wherein said conducting the heat-treatment for said semiconductor substrate comprises heating said element formation surface to a temperature of equal to or higher than 500 degree C.

6. The method according to claim 4, wherein said conducting the heat-treatment for said semiconductor substrate comprises activating the impurity contained in said impurity-implanted region by heating said semiconductor substrate via a spike rapid thermal annealing (spike RTA).

7. The method according to claim 5, wherein said conducting the heat-treatment for said semiconductor substrate comprises activating the impurity contained in said impurity-implanted region by heating said semiconductor substrate via a spike rapid thermal annealing (spike RTA).

8. The method according to claim 3, further comprises providing a silicide layer on an upper portion of said gate electrode and on an upper portion of said source/drain region, after said conducting the heat-treatment for said semiconductor substrate.

9. The method according to claim 1, wherein said irradiating a laser beam under the condition so that said semiconductor substrate is not melted includes irradiating a laser beam so that highest available temperature of said element formation surface is set to a temperature of lower than 1,412 degree C.

10. The method according to claim 3, wherein said irradiating a laser beam under the condition so that said semiconductor substrate is not melted includes irradiating said laser beam so that highest available temperature of said element formation surface is set to a temperature of lower than 1,412 degree C.
